(19) United States
(12) Patent Application Publication
(10) Pub. No.: US 2026/0255544 A1
(43) Pub. Date: Aug. 27, 2026

(54) HEAT DISSIPATION MODULE, HEAT SINK, AND SERVER

(71) Applicants: Inventec (Pudong) Technology Corporation, Shanghai (CN); INVENTEC CORPORATION, Taipei (TW)

(72) Inventor: Qidong Li, Shanghai (CN)

(21) Appl. No.: 19/185,286

(22) Filed: Apr. 22, 2025

(30) Foreign Application Priority Data
Feb. 25, 2025 (CN) 202510213735.0

(51) Int. Cl. H05K 7/20

(52) U.S. Cl. CPC H05K 7/20327; H05K 7/20318; H05K 7/2039; H05K 7/208

(57) ABSTRACT

A heat dissipation module includes: a condenser provided with a first air inlet, a liquid outlet, and a second air inlet, the first air inlet and the second air inlet being respectively arranged at opposite ends of the heat dissipation module in a first direction, and the liquid outlet being arranged in a middle of the condenser and between the first air inlet and the second air inlet; a liquid flow pipe having a first end connected to the liquid outlet; a first gas flow pipe and a second gas flow pipe, a first end of the first gas flow pipe being connected to the first air inlet, and a first end of the second gas flow pipe being connected to the second air inlet; and a first heat dissipation plate and a second heat dissipation plate.

### CROSS-REFERENCE TO RELATED APPLICATIONS

This application claims priority to Chinese patent application No. 2025102137350, filed on February 25, 2025, the disclosure of which is hereby incorporated by reference in its entirety.

### TECHNICAL FIELD

The present disclosure relates to the technical field of heat dissipation of servers, and in particular, to a heat dissipation module, a heat sink, and a server.

### BACKGROUND

With the rapid development of information technology, a demand for artificial intelligence (AI) computing power is gradually increasing, so a market demand for edge AI servers is also constantly increasing. Correspondingly, the power density of chips used for AI computing is increasing, and an increase in power is also accompanied by an increase in heat generation, and electronic components when operating in a high-temperature environment for a long time, will greatly reduce their operational performance and stability.

In a conventional technology, solutions of unidirectional cold-plate liquid cooling and phase-change cold-plate liquid cooling are generally employed to provide heat dissipation services for chips with high heat flux density. However, the unidirectional cold-plate liquid cooling has an extremely limited heat dissipation capacity, making it difficult to meet heat dissipation requirements of chips with gradually increasing heat generation. Although phase-change cold-plate liquid cooling can meet heat dissipation requirements of chips with high heat generation through phase-change latent heat of a liquid, the liquid has large flow resistance, which impairs heat dissipation efficiency, and a gaseous phase is prone to blockage, increasing internal operating pressure of the system.

### SUMMARY

According to various embodiments of the present disclosure, a heat dissipation module is provided.

In a first aspect of the present disclosure, a heat dissipation module is provided, including:

a condenser provided with a first air inlet, a liquid outlet, and a second air inlet, the first air inlet and the second air inlet being respectively arranged at opposite ends of the heat dissipation module in a first direction, and the liquid outlet being arranged in a middle of the condenser and between the first air inlet and the second air inlet;

a liquid flow pipe having a first end connected to the liquid outlet;

a first gas flow pipe and a second gas flow pipe, a first end of the first gas flow pipe being connected to the first air inlet, and a first end of the second gas flow pipe being connected to the second air inlet; and

a first heat dissipation plate and a second heat dissipation plate, a first liquid inlet of the first heat dissipation plate being connected to a second end of the liquid flow pipe, a second liquid inlet of the second heat dissipation plate being connected to the second end of the liquid flow pipe, a first exhaust port of the first heat dissipation plate being connected to a second end of the first gas flow pipe, and a second exhaust port of the second heat dissipation plate being connected to a second end of the second gas flow pipe.

In a second aspect of the present disclosure, a heat sink is further provided, including at least two heat dissipation modules as described above. The at least two heat dissipation modules are arranged side by side in a preset direction.

In a third aspect of the present disclosure, a server is further provided, including:

a functional device module; and

the heat sink as described above, the heat sink cooperating with the functional device module for heat transfer.

### BRIEF DESCRIPTION OF THE DRAWINGS

The accompanying drawings forming part of the present disclosure are intended to provide further understanding of the present disclosure. Exemplary embodiments of the present disclosure and descriptions thereof are intended to illustrate the present disclosure, and do not constitute any inappropriate limitation on the present disclosure.

In order to more clearly illustrate the technical solutions in embodiments of the present disclosure, the accompanying drawings used in the description of the embodiments will be briefly introduced below. Apparently, the accompanying drawings in the following description are only some embodiments of the present disclosure, and other drawings can be obtained by those of ordinary skill in the art from the provided drawings without creative efforts.

FIG. 1 is a schematic view of a heat dissipation module according to an embodiment of the present disclosure.

FIG. 2 is a schematic view of a heat dissipation module according to another embodiment of the present disclosure.

FIG. 3 is a partial enlarged schematic view of portion A in FIG. 1.

FIG. 4 is an exploded view of a first heat dissipation plate and a second heat dissipation plate according to an embodiment.

FIG. 5 is a schematic view of a server according to an embodiment of the present disclosure.

### Illustrations for reference numerals

100: heat dissipation module; 10: condenser; 101: first condensing plates; 102: second condensing plates; 11: first air inlet; 12: liquid outlet; 13: second air inlet; 14: condenser housing; 141: first condensing chamber; 142: second condensing chamber; 15: partition plate; 20: liquid flow pipe; 21: first liquid flow branch pipe; 22: second liquid flow branch pipe; 30: first gas flow pipe; 40: second gas flow pipe; 50: first heat dissipation plate; 60: second heat dissipation plate; 60a: heat dissipation housing; 60b: heat dissipation fin; 60c: mounting assembly; 60d: mounting through hole; 61c: mounting member; 62c: elastic member; 70: first flow distributor; 80: second flow distributor; 90: water distributor; 90a: flow sensor.

### DETAILED DESCRIPTION

To make the above objects, features, and advantages of the present disclosure more comprehensible, specific implementations of the present disclosure are described in detail below with reference to the accompanying drawings. In the following description, numerous specific details are set forth in order to provide a thorough understanding of the present disclosure. However, the present disclosure can be implemented in many other ways different from those described herein, and those skilled in the art can make similar improvements without departing from the connotation of the present disclosure, so the present disclosure is not limited by the specific embodiments disclosed below.

In the description of the present disclosure, it should be understood that if these terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and the like appear, the orientation or positional relationship indicated by these terms is based on the orientation or positional relationship shown in the drawings, which are only for the convenience of describing the present disclosure and simplifying the description, rather than indicating or implying that the device or element referred to must have a specific orientation, be constructed and operated in a specific orientation, and therefore cannot be understood as a limitation to the present disclosure.

In addition, if these terms “first” and “second” appear, these terms are only used for descriptive purposes, and cannot be understood as indicating or implying relative importance or implicitly indicating the number of indicated technical features. Thus, features defined by “first” and “second” may explicitly or implicitly include at least one of the features. In the description of the present disclosure, if a term “a plurality of” appears, it means at least two, such as two, three, etc., unless otherwise specifically defined.

In the present disclosure, unless otherwise clearly specified and limited, if the terms “mount”, “connect”, “couple”, “fix”, and the like appear, these terms should be understood in a broad sense. For example, a connection may be a fixed connection, or a detachable connection; or an integral connection; or may be a mechanical connection, or an electrical connection; or may be a direct connection, or an indirect connection through an intermediate medium; or may be an internal communication between two elements or an interaction relationship between two elements, unless otherwise explicitly specified. A person of ordinary skill in the art may understand specific meanings of the foregoing terms in the present disclosure based on a specific situation.

In the present disclosure, unless otherwise expressly specified and limited, if a first feature is described as “above” or “below” a second feature, it means that the first and second features are in direct contact, or the first and second features are in indirect contact through an intermediate medium. Moreover, the first feature being “above”, “over” and “on” the second feature may be that the first feature is directly above or obliquely above the second feature, or merely indicate that the first feature is higher in level than the second feature. That the first feature is “below”, “under” and “beneath” the second feature may mean that the first feature is directly below or obliquely below the second feature, or merely means that the first feature is lower in level than the second feature.

It should be noted that if an element is referred to as being “fixed to” or “disposed on” another element, it can be directly on the other element or intervening elements may also be present. If an element is referred to as being “connected” to another element, it can be directly connected to the other element or intervening elements may be present. If present, the terms “vertical”, “horizontal”, “upper”, “lower”, “left”, “right” and similar expressions used in the present disclosure are only for the purpose of illustration, and do not represent the unique embodiment.

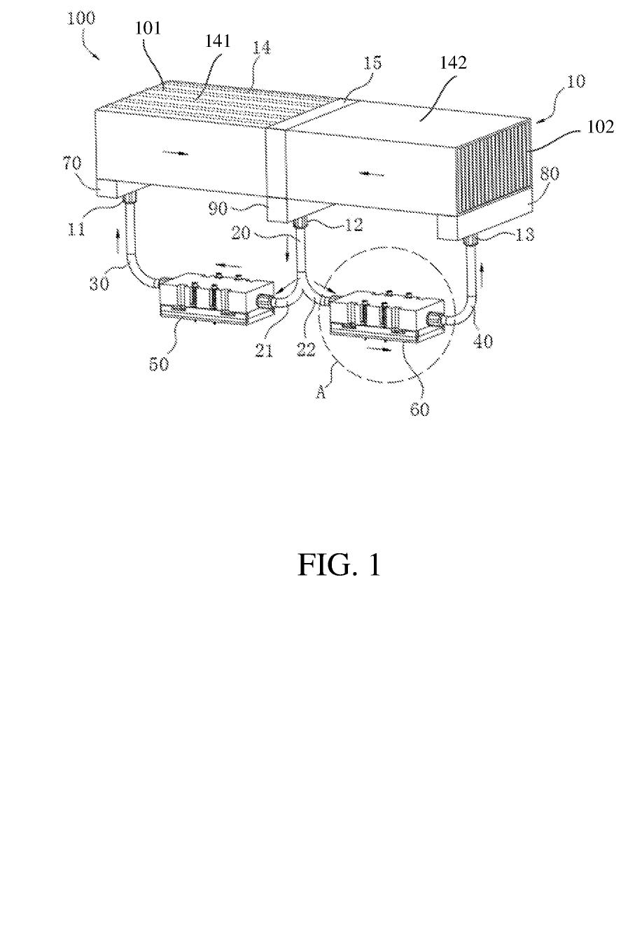

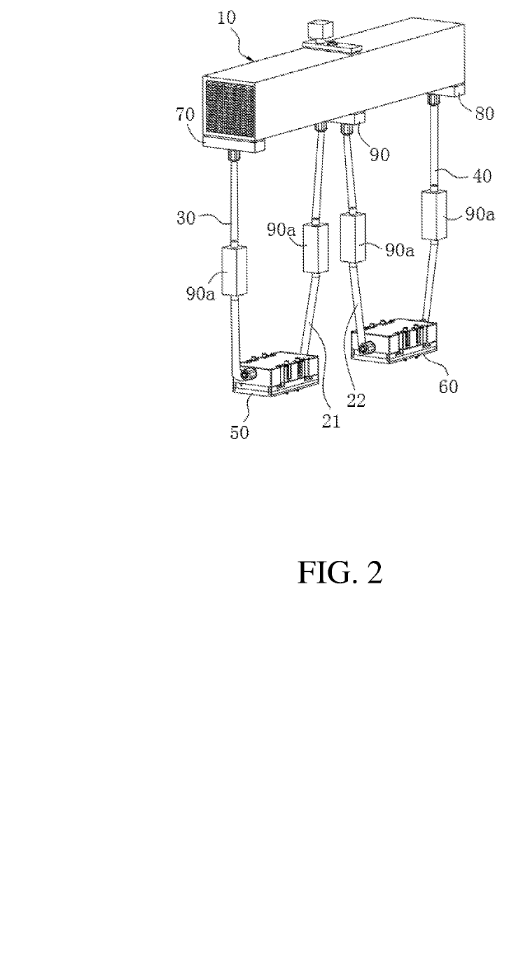

Refer to FIG. 1 and FIG. 2, heat dissipation modules 100 according to two different embodiments of the present disclosure are illustrated. Each heat dissipation module 100 includes a condenser 10, a liquid flow pipe 20, a first gas flow pipe 30, a second gas flow pipe 40, a first heat dissipation plate 50, and a second heat dissipation plate 60. The heat dissipation modules 100 according to the present disclosure can effectively reduce liquid flow resistance and ensure normal operating pressure inside the system, solving problems of large flow resistance of the liquid and high internal operating pressure of the system in the related art.

The condenser 10 is provided with a first air inlet 11, a liquid outlet 12, and a second air inlet 13. The first air inlet 11 and the second air inlet 13 are respectively arranged at opposite ends of the heat dissipation module 100 in a first direction. The liquid outlet 12 is arranged in the middle of the condenser 10 and between the first air inlet 11 and the second air inlet 13. The liquid flow pipe 20 has a first end connected to the liquid outlet 12. An end of the first gas flow pipe 30 is connected to the first air inlet 11. An end of the second gas flow pipe 40 is connected to the second air inlet 13. A first liquid inlet of the first heat dissipation plate 50 is connected to a second end of the liquid flow pipe 20. A second liquid inlet of the second heat dissipation plate 60 is connected to the second end of the liquid flow pipe 20. A first exhaust port of the first heat dissipation plate 50 is connected to another end of the first gas flow pipe 30, and a second exhaust port of the second heat dissipation plate 60 is connected to another end of the second gas flow pipe 40.

The heat dissipation module 100 according to the present application is applied to a server and is configured to cool down a chip with high heat generation. In use, the heat dissipation module 100 is mounted on a main plate. The first heat dissipation plate 50 and the second heat dissipation plate 60 respectively cooperate with chips for heat transfer (for example, by a direct contact or indirect contact to achieve heat transfer). During operation, heat generated by the chips is transferred to the first heat dissipation plate 50 and the second heat dissipation plate 60, respectively, so that cooling liquid inside the first heat dissipation plate 50 and the second heat dissipation plate 60 absorbs heat, heats up, and vaporizes into gas. The gas may then flow to the first air inlet 11 through the first gas flow pipe 30, and flow to the second air inlet 13 of the condenser 10 through the second gas flow pipe 40, respectively, and then the gas flows into the interior of the condenser 10 through the first air inlet 11 and the second air inlet 13 from two ends of the condenser 10 in the first direction, respectively. The gas cools down by exchanging heat with the cooling medium inside the condenser 10, so that the gas is condensed into a liquid. The liquid converges at the liquid outlet 12 and finally flows back to the first heat dissipation plate 50 and the second heat dissipation plate 60 through the liquid flow pipe 20. Through continuous cycling of the above operating process, the chips can be efficiently heat-dissipated and cooled by phase-change liquid cooling. Moreover, a flow path along which the gas flows and is condensed into the liquid in the condenser 10 is shortened by at least half, which effectively reduces liquid flow resistance, helps to improve heat dissipation efficiency of the heat dissipation module 100. Moreover, easy blockage of the gaseous phase is prevented, ensuring normal operating pressure inside the system.

It is to be noted that the first direction of the heat dissipation module 100 refers to a length direction of the condenser 10. In this case, the first air inlet 11 and the second air inlet 13 are respectively arranged at two ends of the condenser 10 in the length direction, and the liquid outlet 12 is arranged in the middle of the condenser 10. in this way, during liquefaction of the gas into the liquid in the condenser 10, the length of the gas flow from the first air inlet 11 to the liquid outlet 12 and the length of the gas flow from the second air inlet 13 to the liquid outlet 12 are only half the length of the condenser 10, which greatly shortens a length of a return flow path of the cooling liquid through the condenser 10, and reduces the liquid flow resistance.

It is further to be noted that a principle of condensing the gas into the liquid by the condenser 10 is based on the principle of heat exchange. After a high-temperature gas enters the condenser 10, the temperature of the gas gradually decreases through heat exchange with the cooling medium (which is generally cooling liquid or air, and which is cooling liquid herein, such as water). As the temperature decreases, thermal motion of gas molecules slows down, a distance between the molecules decreases, so that a gaseous substance gradually turns into a liquid substance, completing a condensation process. The arrows in FIG. 1 indicate phase-change circulation flow directions of the gas and the cooling liquid.

A second direction of the heat dissipation module 100 may be specifically refers to a width direction of the condenser 10.

Opening sizes of the first air inlet 11 and the second air inlet 13 are smaller than a width of the condenser 10.

Still referring to FIG. 1 and FIG. 2, on the basis of the above embodiments, the heat dissipation module 100 further includes a first flow distributor 70. The first flow distributor 70 is mounted at the first air inlet 11. The first flow distributor 70 is connected to an end of the first gas flow pipe 30 away from the first heat dissipation plate 50.

Similarly, the heat dissipation module 100 further includes a second flow distributor 80. The second flow distributor 80 is mounted at the second air inlet 13. The second flow distributor 80 is connected to an end of the second gas flow pipe 40 away from the second heat dissipation plate 60.

Through the arrangement of the first flow distributor 70 and the second flow distributor 80, the gas inputted into the condenser 10 through the first gas flow pipe 30 and the second gas flow pipe 40 can be distributed and diffused, so that the gas can be evenly distributed in a cross-sectional space of the condenser 10 as soon as the gas flows into the condenser 10, thereby increasing a heat exchange area of the gas and improving condensation efficiency of the gas.

Further, in another embodiment, the heat dissipation module 100 shown in FIG. 2 further includes a water distributor 90. The water distributor 90 is mounted at the liquid outlet 12. The liquid flow pipe 20 includes a first liquid flow branch pipe 21 and a second liquid flow branch pipe 22. The water distributor 90 is connected to the first liquid flow branch pipe 21 and the second liquid flow branch pipe 22. The water distributor 90 can evenly distribute the cooling liquid, which converges inside the water distributor 90 and is formed by condensation of the gas, to the first liquid flow branch pipe 21 and the second liquid flow branch pipe 22, so as to ensure that flow rates of the cooling liquid flowing back to the first heat dissipation plate 50 and the second heat dissipation plate 60 are equal and sufficient. This, on the one hand, ensures that the first heat dissipation plate 50 and the second heat dissipation plate 60 have a same cooling effect on the chips and effectively dissipate the heat of the chips; and on the other hand, ensures that the first heat dissipation plate 50 and the second heat dissipation plate 60 are replenished with liquid in time, preventing drying out which would compromise the service life of the first heat dissipation plate 50, the second heat dissipation plate 60, and the connected chips.

Still referring to FIG. 1, in an optional embodiment, the condenser 10 includes a condenser housing 14 and a partition plate 15. The partition plate 15 is mounted inside the condenser housing 14 to divide an inner cavity of the condenser housing 14 into a first condensing chamber 141 and a second condensing chamber 142. A medium flow direction in the first condensing chamber 141 is from the first air inlet 11 to the liquid outlet 12, and a medium flow direction in the second condensing chamber 142 is from the second air inlet 13 to the liquid outlet 12.

In this way, the partition plate 15 can prevent noise caused by collision of opposing flows of the liquid or the gas-liquid mixed medium in the first condensing chamber 141 and the second condensing chamber 142, so that it can ensure that two streams of liquid formed after condensation can flow directly and separately to the liquid outlet 12 and converge in the water distributor 90, thereby improving effectiveness of the cooling liquid flowing in the condenser 10.

Further, on the basis of the above embodiment, the condenser 10 further includes at least two first condensing plates 101 and at least two second condensing plates 102. The at least two first condensing plates 101 are mounted in the first condensing chamber 141, and arranged side by side and spaced apart in the second direction of the heat dissipation module 100. A first condensing flow channel is formed between two adjacent first condensing plates 101. The at least two second condensing plates 102 are mounted in the second condensing chamber 142, and spaced apart in the second direction of the heat dissipation module 100. A second condensing flow channel is formed between two adjacent second condensing plates 102. The second direction intersects the first direction.

After flowing into the condenser 10 from the first air inlet 11 and the second air inlet 13, the gas may be respectively distributed into each first condensing flow channel and into each second condensing flow channel, and then respectively contact a plurality of first condensing plates 101 and a plurality of second condensing plates 102 at the same time, and the heat exchange occurs, which greatly improves cooling efficiency, so that the gas can be condensed into cooling liquid more quickly and returned for recycling.

It is easy to understand that the cooling medium in the condenser 10 in the above embodiments may be specifically the air in the first condensing flow channel and the second condensing flow channel. The air transfers the heat of the gas to the first condensing plate 101 and the second condensing plate 102, and then the heat is dissipated to an external environment through the condenser housing 14.

Alternatively, as an alternative to the above embodiments, the condenser 10 further includes at least two first condensing plates 101 and at least two second condensing plates 102. The at least two first condensing plates 101 are mounted in the first condensing chamber 141 and arranged side by side and spaced apart in the second direction of the heat dissipation module 100. A first condensing flow channel is formed between two adjacent first condensing plates 101, a first cavity is formed inside each of the first condensing plates 101. The first cavity is provided with a cooling medium. The at least two second condensing plates 102 are mounted in the second condensing chamber 142 and spaced apart in the second direction of the heat dissipation module 100. A second condensing flow channel is formed between two adjacent second condensing plates 102, a second cavity is formed inside each of the second condensing plates 102. The second cavity is provided with a cooling medium. The second direction intersects the first direction.

Different from the above embodiments, the cooling medium contained in the first condensing plate 101 and the second condensing plate 102 performs heat exchange with the gas, thereby absorbing heat and cooling the gas, so that the gas is condensed into the cooling liquid.

It is to be noted that flow sensors 90a may be mounted in the first liquid flow branch pipe 21, the second liquid flow branch pipe 22, the first gas flow pipe 30, and the second gas flow pipe 40 respectively to monitor the flow of the gas and the cooling liquid, so as to detect problems such as poor flow in time.

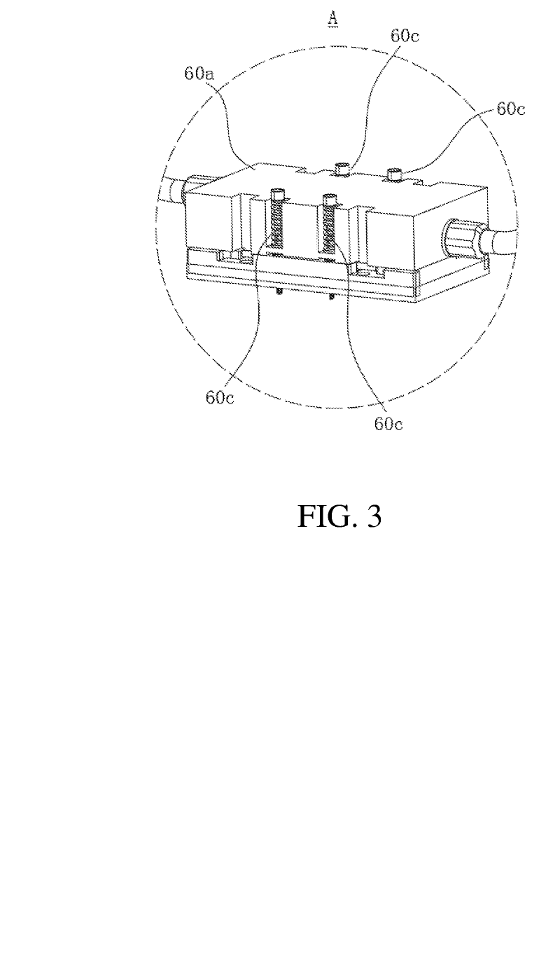

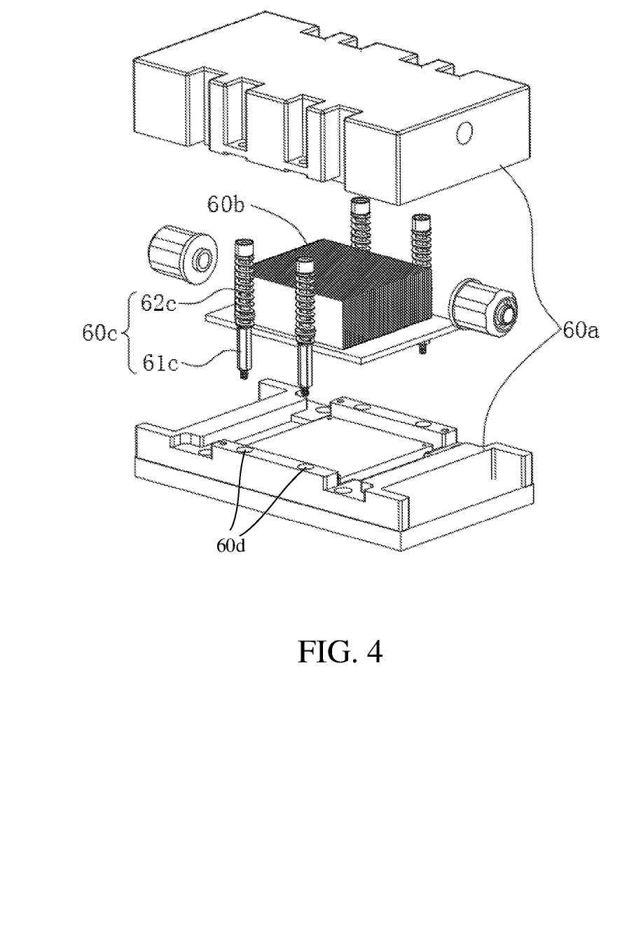

Still referring to FIG. 3 and FIG. 4, in addition, based on any of the above embodiments, each of the first heat dissipation plate 50 and the second heat dissipation plate 60 includes a heat dissipation housing 60a and at least two heat dissipation fins 60b. A mounting cavity is formed inside the heat dissipation housing 60a. The at least two heat dissipation fins 60b are mounted in the mounting cavity and arranged side by side and spaced apart in the second direction of the heat dissipation module 100. A liquid flow channel is formed between two adjacent heat dissipation fins 60b.

In use, the heat dissipation housing 60a is directly attached to or in indirect contact with a to-be-dissipated chip through a heat transfer medium (such as thermal conductive adhesive), so that high-temperature heat generated by the chip during operation can be transferred to the heat dissipation housing 60a. Then, the heat is further transferred to the heat dissipation fins 60b to exchange heat with the cooling liquid in the mounting cavity. The cooling liquid absorbs heat, heats up, and vaporizes into a gas, thereby cooling the chip. The generated high-temperature gas flows into the condenser 10 and is re-condensed into cooling liquid, and then flows back into the heat dissipation housing 60a, thereby realizing recycling and continuous heat dissipation of the chip.

Further, each of the first heat dissipation plate 50 and the second heat dissipation plate 60 further includes a mounting assembly 60c. The mounting assembly 60c includes a mounting member 61c and an elastic member 62c. The heat dissipation housing 60a is provided with a mounting through hole 60d. The mounting member 61c movably extends through the mounting through hole 60d. The elastic member 62c is positioned between and abuts against the heat dissipation housing 60a and the mounting member 61c. Therefore, the first heat dissipation plate 50 and the second heat dissipation plate 60 can be mounted on the main plate through the mounting assembly 60c, so that the heat dissipation housing 60a cooperates with the chip for heat transfer.

Specifically, the mounting member 61c extends through the mounting through hole 60d and is fixedly connected to the main plate, in which case the elastic member 62c is compressed and stores energy. When the first heat dissipation plate 50 and the second heat dissipation plate 60 are removed, the mounting member 61c is released from the main plate, and the elastic member 62c releases an elastic force, so that the mounting member 61c can automatically move away from the main plate.

For example, the mounting member 61c is a threaded component such as a screw or a bolt to reduce the difficulty of mounting and removal and ensure connection strength.

In an embodiment, a plurality of, for example, four, mounting assemblies 60c are provided. The four mounting assemblies 60c are arranged in a rectangular shape at an outer periphery of the heat dissipation housing 60a, thereby further improving the connection reliability by increasing a number of connection points with the main plate.

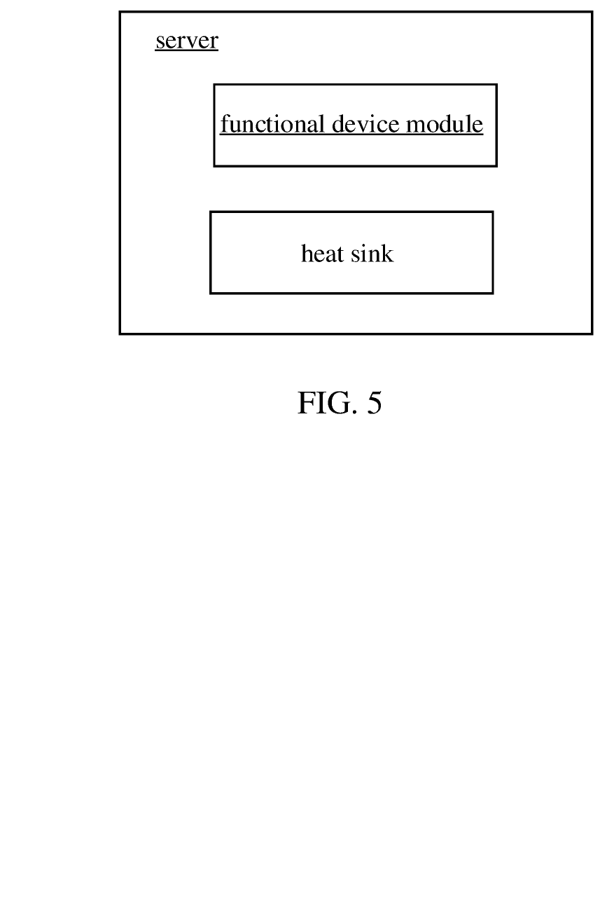

In addition, the present disclosure further provides a server. As shown in FIG. 5, the server includes a functional device module and a heat sink. The heat sink cooperates with the functional device module for heat transfer. The heat sink includes at least two heat dissipation modules 100 as described in any one of the above embodiments. The at least two heat dissipation modules 100 are arranged side by side in a preset direction.

The functional device module specifically includes a main plate and a chip. The chip is mounted on the main plate.

A plurality of chips may be arranged in an array on the main plate, so the heat sink formed by the at least two heat dissipation modules 100 can simultaneously meet heat dissipation and cooling requirements of the plurality of chips.

The heat dissipation module according to the present disclosure is applied to the server and is configured to cool down the chip with high heat generation. In use, the heat dissipation module is mounted on the main plate, the first heat dissipation plate and the second heat dissipation plate respectively cooperate with corresponding chips for heat transfer (for example, by direct contact or indirect contact to achieve heat transfer). During operation, heat generated by the chips is transferred to the first heat dissipation plate and the second heat dissipation plate, so that cooling liquid inside the first heat dissipation plate and the second heat dissipation plate absorbs heat, heats up, and vaporizes into gas. The gas may then flow to the first air inlet and the second air inlet of the condenser respectively through the first gas flow pipe and the second gas flow pipe, and then the gas flows into the interior of the condenser through the first air inlet and the second air inlet from two ends of the condenser in the first direction, respectively. The gas cools down by exchanging heat with the cooling medium inside the condenser, so that the gas is condensed into a liquid. The liquid converges at the liquid outlet and finally flows back to the first heat dissipation plate and the second heat dissipation plate through the liquid flow pipe. Through continuous cycling of the above operating process, the chip can be efficiently heat-dissipated and cooled by phase-change liquid cooling. Moreover, the flow path along which the gas flows and is condensed into the liquid in the condenser is shortened by at least half, which effectively reduces liquid flow resistance, helps to improve heat dissipation efficiency of the heat dissipation module. Moreover, easy blockage of the gas phase is prevented, ensuring normal operating pressure inside the system.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

What is claimed is:

1. A heat dissipation module, comprising:
a condenser provided with a first air inlet, a liquid outlet, and a second air inlet, the first air inlet and the second air inlet being respectively arranged at opposite ends of the heat dissipation module in a first direction, and the liquid outlet being arranged in a middle of the condenser and between the first air inlet and the second air inlet;
a liquid flow pipe having a first end connected to the liquid outlet;
a first gas flow pipe and a second gas flow pipe, a first end of the first gas flow pipe being connected to the first air inlet, and a first end of the second gas flow pipe being connected to the second air inlet; and
a first heat dissipation plate and a second heat dissipation plate, a first liquid inlet of the first heat dissipation plate being connected to a second end of the liquid flow pipe, a second liquid inlet of the second heat dissipation plate being connected to the second end of the liquid flow pipe, a first exhaust port of the first heat dissipation plate being connected to a second end of the first gas flow pipe, and a second exhaust port of the second heat dissipation plate being connected to a second end of the second gas flow pipe.

2. The heat dissipation module according to claim 1, further comprising a first flow distributor mounted at the first air inlet, wherein the first flow distributor is connected to the first end of the first gas flow pipe away from the first heat dissipation plate.

3. The heat dissipation module according to claim 1, further comprising a second flow distributor mounted at the second air inlet, wherein the second flow distributor is connected to the first end of the second gas flow pipe away from the second heat dissipation plate.

4. The heat dissipation module according to claim 1, further comprising a water distributor mounted at the liquid outlet, wherein the liquid flow pipe comprises a first liquid flow branch pipe and a second liquid flow branch pipe; and the water distributor is connected to the first liquid flow branch pipe and the second liquid flow branch pipe.

5. The heat dissipation module according to claim 1, wherein the condenser comprises a condenser housing and a partition plate, wherein the partition plate is mounted in the condenser housing to divide an inner cavity of the condenser housing into a first condensing chamber and a second condensing chamber; a medium flow direction in the first condensing chamber is from the first air inlet to the liquid outlet, and a medium flow direction in the second condensing chamber is from the second air inlet to the liquid outlet.

6. The heat dissipation module according to claim 5, wherein the condenser further comprises at least two first condensing plates and at least two second condensing plates, wherein the at least two first condensing plates are mounted in the first condensing chamber and arranged side by side and spaced apart in a second direction of the heat dissipation module, a first condensing flow channel is formed between two adjacent first condensing plates; the at least two second condensing plates are mounted in the second condensing chamber and spaced apart in the second direction of the heat dissipation module, and a second condensing flow channel is formed between two adjacent second condensing plates; wherein the second direction intersects the first direction.

7. The heat dissipation module according to claim 5, wherein the condenser further comprises at least two first condensing plates and at least two second condensing plates, wherein the at least two first condensing plates are mounted in the first condensing chamber and arranged side by side and spaced apart in a second direction of the heat dissipation module, a first condensing flow channel is formed between two adjacent first condensing plates, and a first cavity is formed inside each of the first condensing plates, the first cavity being provided with a cooling medium; and the at least two second condensing plates are mounted in the second condensing chamber and spaced apart in the second direction of the heat dissipation module, a second condensing flow channel is formed between two adjacent second condensing plates, and a second cavity is formed inside each of the second condensing plates, the second cavity being provided with a cooling medium; wherein the second direction intersects the first direction.

8. The heat dissipation module according to claim 1, wherein each of the first heat dissipation plate and the second heat dissipation plate comprises a heat dissipation housing and at least two heat dissipation fins, wherein a mounting cavity is formed inside the heat dissipation housing, the at least two heat dissipation fins are mounted in the mounting cavity and arranged side by side and spaced apart in a second direction of the heat dissipation module; and a liquid flow channel is formed between two adjacent heat dissipation fins.

9. The heat dissipation module according to claim 8, wherein each of the first heat dissipation plate and the second heat dissipation plate further comprises a mounting assembly comprising a mounting member and an elastic member, wherein the heat dissipation housing is provided with a mounting through hole, the mounting member movably extends through the mounting through hole; and the elastic member is positioned between and abuts against the heat dissipation housing and the mounting member.

10. A heat sink, comprising at least two heat dissipation modules according to claim 1, wherein the at least two heat dissipation modules are arranged side by side in a preset direction.

11. A server, comprising:
a functional device module; and
the heat sink according to claim 10, wherein the heat sink cooperates with the functional device module for heat transfer.
